(19) United States
(12) Patent Application Publication
(10) Pub. No.: US 2026/0136843 A1
(43) Pub. Date: May 14, 2026

(54) ETCHING A PHASE CHANGE MATERIAL

(71) Applicants: INTERNATIONAL BUSINESS MACHINES CORPORATION, ARMONK, NY (US); TOKYO ELECTRON LIMITED, Tokyo (JP)

(72) Inventors: Luxherta Buzi, Chappaqua, NY (US); Robert L. Bruce, White Plains, NY (US); Devi Koty, Hopewell Junction, NY (US)

(21) Appl. No.: 18/940,569

(22) Filed: Nov. 7, 2024

(51) Int. Cl. H10N 70/00; H01J 37/32; H10B 63/10; H10N 70/20

(52) U.S. Cl. CPC H10N 70/063; H01J 37/32449; H01J 37/32724; H10B 63/10; H10N 70/231; H01J 2237/002; H01J 2237/334

(57) ABSTRACT

Provided are a method for etching a phase change material of a phase change memory device and a semiconductor device formed according to the method. A temperature of the phase change memory device is lowered to a target temperature. A plasma etching process is applied to pattern the phase change material in response to cooling the temperature of the phase change memory device to the target temperature.

### BACKGROUND OF THE INVENTION

The present invention relates to semiconductor memory cells and methods of

forming the same. More particularly, the present application relates to non-volatile phase change memory cells and methods of forming such cells.

Phase change memory semiconductor devices are used to form non-volatile random access memory, such as 3D cross-point memory. In phase change memory cells, information is stored in materials that can be manipulated into different phases, e.g., the amorphous phase and the crystalline phase. Such materials are referred to as phase change materials. The amorphous phase and the crystalline phase are typically two phases used for bit storage of binary values since they have two detectable differences in electrical resistance. The amorphous phase has a higher resistance than the crystalline phase.

Phase change memory cells may be formed in a plasma chamber using suitable gases to etch the material. To avoid damage to the phase change material, a passivation gas, such as methane (CH₄) may be introduced to provide sidewall passivation to limit diffusion into the bulk of the phase change material. To remove the passivation layers or polymers that form on the sidewall, a separate clean-up step is needed to remove the etching residue and the damaged layers of the phase change material.

### SUMMARY

Provided are a method for etching a phase change material of a phase change memory device and a semiconductor device formed according to the method. A temperature of the phase change memory device is lowered to a target temperature. A plasma etching process is applied to pattern the phase change material in response to cooling the temperature of the phase change memory device to the target temperature.

Further provided are an additional method for etching a phase change material of a phase change memory device and a semiconductor device formed according to the method. The phase change memory device is in a stack including a substrate, a plurality of lower layers between the substrate and a lower side of the phase change material, and a plurality of upper layers above an upper side of the phase change material. The upper layers including at least one layer of the upper layers is etched. A temperature of the phase change memory device is decreased to a target temperature after etching the upper layers. A plasma etching process is applied to pattern the phase change material in response to the decreasing the temperature of the phase change memory device to the target temperature.

Further provided are an additional method for etching a phase change material of a phase change memory device and a semiconductor device formed according to the method. Layers of a stack including the phase change memory device are plasma etched above the phase change material at a first temperature. The phase change material is plasma etched with a halogen at a second temperature to form a phase change memory cell. The second temperature is less than the first temperature. The etched phase change memory cell comprises sidewall regions of the phase change memory cell on sides of the phase change material. The etching results in an interface region that extends along an outer surface of the sidewall regions. The interface region includes trace elements of halogen used in etching the phase change memory cell. The interface region and the sidewall are free of carbon. The etching results in a bulk region of the phase change memory cell is between the sidewalls. A top electrode formed on an upper surface of the phase change memory cell for enabling read or write access to the phase change memory cell.

### BRIEF DESCRIPTION OF THE DRAWINGS

FIG. 1 illustrates a method for forming and etching a phase change material in a plasma chamber.

FIG. 2A illustrates a phase change device stack on a substrate.

FIG. 2B illustrates an etched phase change memory cell.

FIG. 3 illustrates an exemplary, non-limiting semiconductor fabrication processing apparatus in which the present methods can be implemented.

### DETAILED DESCRIPTION

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The description herein provides examples of embodiments of the invention, and variations and substitutions may be made in other embodiments. Several examples will now be provided to further clarify various embodiments of the present disclosure.

Example 1 is a method for etching a phase change material of a phase change memory device. A temperature of the phase change memory device is lowered to a target temperature. A plasma etching process is applied to pattern the phase change material in response to cooling the temperature of the phase change memory device to the target temperature. Thus, embodiments advantageously allow for plasma etching at a low temperature to introduce only an elemental trace of the halogen to the phase change material, inhibit damage to the phase change material, and avoid redeposition of materials on the sidewall of the phase change material.

Example 2: The limitations of any of Examples 1 and 3-8 may optionally include that the target temperature is between approximately −50° C. and −20° C. Thus, embodiments advantageously allow for plasma etching at a lower temperature to avoid introduction of passivation elements that may damage the phase change material.

Example 3: The limitations of any of Examples 1, 2 and 4-8 may optionally include that no passivation gas is introduced during the plasma etching process. Thus, embodiments advantageously allow for plasma etching without introduction of passivation elements to avoid damage to the phase change material.

Example 4: The limitations of any of Examples 1-3 and 5-8 may optionally include forming a plasma gas for the plasma etching process using halogens. Thus, embodiments advantageously allow for plasma etching with halogens to avoid damage to the phase change material, leaving only trace amounts of halogen in the phase change material.

Example 5: The limitations of any of Examples 1-4 and 6-8 may optionally include that the plasma gas comprises chlorine gas. Thus, embodiments advantageously allow for plasma etching with chlorine gas to avoid damage to the phase change material, leaving only trace amounts of chlorine in the phase change material.

Example 6: The limitations of any of Examples 1-5, 7, and 8 may optionally include that the plasma etching processes uses argon for physical etching and uses chlorine for chemical etching of the pattern on the phase change material. Thus, embodiments advantageously allow for chemical etching with chlorine and physical etching with argon to avoid damage to the phase change material, leaving only trace amounts of the chlorine in the phase change material.

Example 7: The limitations of any of Examples 1-6 and 8 may optionally include that the argon is introduced at a flow rate of 200 standard cubic centimeters per minute (sccm) and the chlorine is introduced at a flow rate of 15 sccm. Thus, embodiments advantageously allow for chemical etching with chlorine and physical etching with argon at specified flow rates to avoid damage to the phase change material, leaving only trace amounts of the chlorine in the phase change material.

Example 8: The limitations of any of Examples 1-7 may optionally include that the plasma etching at the target temperature occurs without redeposition on sidewalls of the phase change material. Thus, embodiments advantageously allow for etching without redeposition on the sidewalls that could otherwise damage the phase change material. Etching without redeposition on the sidewalls further inhibits damage to the bulk of the phase change material.

Example 9 is a method for etching a phase change material of a phase change memory device. The phase change memory device is in a stack including a substrate, a plurality of lower layers between the substrate and a lower side of the phase change material, and a plurality of upper layers above an upper side of the phase change material. The upper layers including at least one layer of the upper layers is etched. A temperature of the phase change memory device is decreased to a target temperature after etching the upper layers. A plasma etching process is applied to pattern the phase change material in response to the decreasing the temperature of the phase change memory device to the target temperature. Thus, embodiments advantageously allow for plasma etching at a reduced temperature to inhibit damage to the phase change material and avoid redeposition of materials on the sidewall of the phase change material.

Example 10: The limitations of any of Examples 9 and 11-14 may optionally include that the target temperature is between approximately −50° C. and −20° C. Thus, embodiments advantageously allow for etching at a sufficiently low temperature without introduction of a passivation gas such that polymers, carbon and other elements are absent from the phase change memory cell, including the interface region, sidewall, and bulk region of the phase change material.

Example 11: The limitations of any of Examples 9, 10, and 12-14 may optionally include that the target temperature comprises a first target temperature, wherein a first upper layer of the upper layers is adjacent to the phase change material in the stack, and wherein the first upper layer is etched at approximately a second target temperature higher than the first target temperature. Thus, embodiments advantageously allow for etching of upper layers at a higher temperature than etching the phase change material because there is not the concern of damaging the upper layers being removed to reach the phase change material.

Example 12: The limitations of any of Examples 9-11, 13, and 14 may optionally include that the second target temperature is between approximately 40° C. and 80° C. Thus, embodiments advantageously allow for etching of upper layers at a higher temperature than etching the phase change material because there is not the concern of damaging the upper layers being removed to reach the phase change material.

Example 13: The limitations of any of Examples 9-12 and 14 may optionally include that the plasma etching process uses halogen chemistry to pattern the phase change material. Thus, embodiments advantageously allow for plasma etching with halogens to avoid damage to the phase change material, leaving only trace amounts of halogen in the phase change material.

Example 14: The limitations of any of Examples 9-13 may optionally include that the upper layers include a titanium nitride layer, a silicon nitride layer, an organic planarization layer, a silicon-containing anti-reflective coating layer, a photoresist layer. The upper layers are etched at temperatures higher than the target temperature to reach the phase change material. Thus, embodiments advantageously allow for etching of upper layers at a higher temperature than etching the phase change material because there is not the concern of damaging the upper layers being removed to reach the phase change material.

Example 15 is a method for etching a phase change material of a phase change memory device. Layers of a stack including the phase change memory device are plasma etched above the phase change material at a first temperature. The phase change material is plasma etched with a halogen at a second temperature to form a phase change memory cell. The second temperature is less than the first temperature. The etched phase change memory cell comprises sidewall regions of the phase change memory cell on sides of the phase change material. The etching results in an interface region that extends along an outer surface of the sidewall regions. The interface region includes trace elements of halogen used in etching the phase change memory cell. The interface region and the sidewall are free of carbon. The etching results in a bulk region of the phase change memory cell is between the sidewalls. A top electrode formed on an upper surface of the phase change memory cell for enabling read or write access to the phase change memory cell. Thus, embodiments advantageously allow for forming the interface region and sidewall free of carbon. Introduction of carbon in the sidewall and interface may result in damage to the phase change material negatively impacting the performance of the phase change memory cell.

Example 16: The limitations of any of Examples 15 and 17-21 may optionally include the plasma etching with the halogen forms the bulk region free of carbon. Thus, embodiments advantageously allow for forming the bulk region free of carbon. Introduction of carbon in the sidewall and interface may result in damage to the phase change material negatively impacting the performance of the phase change memory cell.

Example 17: The limitations of any of Examples 15, 16 and 18-21 may optionally include that the plasma etching with the halogen forms the sidewall region with elemental traces of the halogen at lower concentrations than the elemental traces of the halogen on the interface region. Thus, embodiments advantageously allow for forming the sidewall region with lower concentration of elemental traces of halogen than the interface region, because the concentration of halogen in the interface region has less impact on performance of the phase change memory cell than concentrations in the sidewall region.

Example 18: The limitations of any of Examples 15-17 and 19-21 may optionally include forming a dielectric material to surround the phase change memory cell and in contact with the interface region. Thus, embodiments advantageously allow for forming the dielectric material around the phase change material to isolate the phase change memory cell to avoid electrical interference.

Example 19: The limitations of any of Examples 15-18, 20, and 21 may optionally include that a depth of the sidewall region is less than a depth of the bulk region.

Example 20: The limitations of any of Examples 15-19 and 21 may optionally include that the halogen comprises chlorine. Thus, embodiments advantageously allow for plasma etching with chlorine to avoid damage to the phase change material, leaving only trace amounts of chlorine in the phase change material.

Example 21: A semiconductor device formed according to the operations of any of Examples 1-20.

Phase change memory materials are sensitive to air exposure and/or damage experienced during production. For instance, the oxidation of exposed phase change materials can undesirably lead to changes in its crystallization temperature and composition. Further, the etching processes used during fabrication of the phase change memory device can damage the sidewall of the phase change material and redeposit the materials being etched on the sidewall. Damage and residue along the sidewall may impact the switching behavior of the phase change material.

Described embodiments provide an improved plasma etching process for the phase change memory device without introducing a passivation gas. In the described embodiments, after etching the lithographic stack, the temperature of the phase change device wafer is lowered to a point where cryo-etching using a halogen gas may be performed at a low temperature to etch the phase change material. Etching the phase change material with a halogen gas at a lower cryo-etching temperature, without introducing a passivation gas, inhibits damage to the bulk of the phase change material. Yet further, cryo-etching will cause less oxidation of the sidewall.

Further, by avoiding introduction of passivation gas during the etching process, there is no redeposition of the passivation gas on the sidewalls that needs to be removed in a subsequent clean-up process. Such subsequent clean-up processes also produce a residue on the etched phase change material. Thus, avoiding the clean-up process eliminates the clean-up step and avoids deposition of clean-up materials during a clean-up process.

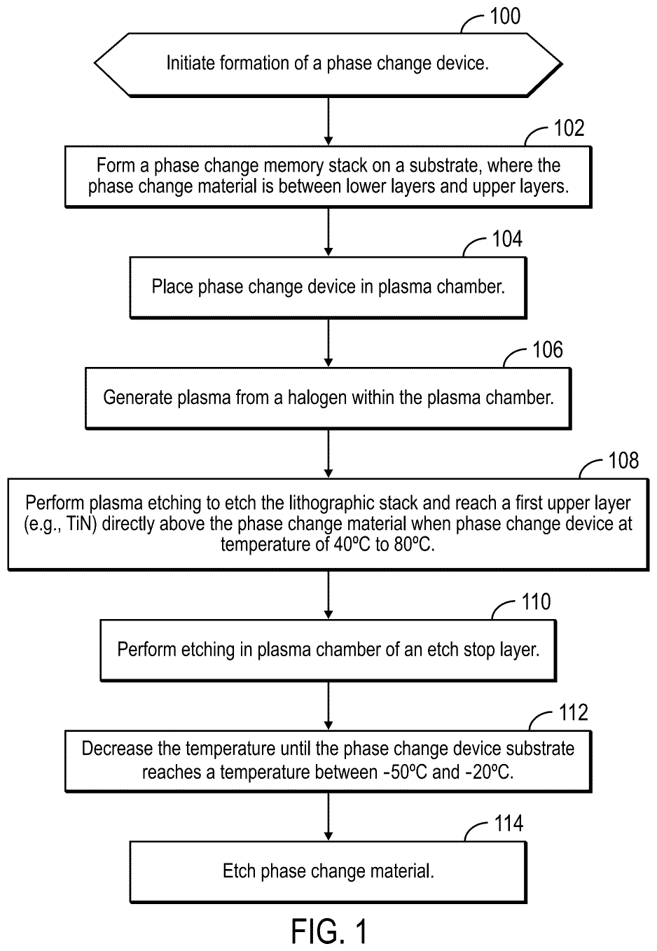

FIG. 1 illustrates an improved process for fabricating a phase change memory device. Upon initiating (at block 100) formation of a phase change device, a phase change memory stack is formed (at block 102) on a substrate. The phase change material is located between lower layers above the substrate and upper layers. According to an exemplary embodiment, the substrate is a bulk semiconductor wafer, such as a bulk silicon (Si), bulk germanium (Ge), bulk silicon germanium (SiGe) and/or bulk III-V semiconductor wafer. Alternatively, the substrate can be a semiconductor-on-insulator (SOI) wafer. An SOI wafer includes an SOI layer separated from an underlying substrate by a buried insulator. When the buried insulator is an oxide, it is also referred to herein as a ‘buried oxide’ or ‘BOX.’ The SOI layer can include any suitable semiconductor material(s), such as Si, Ge, SiGe and/or a III-V semiconductor. Further, the substrate may already have pre-built structures such as transistors, diodes, capacitors, resistors, interconnects, wiring, etc.

A wide variety of materials can be employed as the phase change material in accordance with the present techniques. In the sense that it can exist in amorphous and crystalline form, almost any material is a phase change material, including metals, semiconductors or insulators. However, only a small group of materials have the properties that makes them technologically useful phase change materials, such as a high on/off resistance ratio, fast switching times and good data retention. Many technologically relevant phase change materials are chalcogenides, meaning that they contain one or more chalcogenide elements. Chalcogenide elements are those elements in Group 16 of the periodic table, e.g., sulfur(S), selenium (Se) and/or tellurium (Te).

Thus, according to one exemplary embodiment, the present phase change material is a chalcogenide alloy and, more particularly, a chalcogenide alloy that includes the chalcogenide element Te in addition to other elements such as antimony (Sb) and/or germanium (Ge), forming the alloys Sb₂Te₃, GeTe, and/or Ge₂Sb₂Te₅ (‘GST 225’ or simply ‘GST’). It is notable, however, that other technologically relevant materials are also contemplated herein for use as the present phase change material that are not chalcogenides, such as but not limited to, III-V semiconductor materials (such as gallium antimonide (GaSb)) and/or Ge—Sb based alloys. Further, additional elements such as silver (Ag), indium (In), nitrogen (N), silicon (Si) and/or bismuth (Bi) can be added to any of the above phase change materials to optimize their properties.

The present phase change material can be switched between two states, a poly-crystalline (or single-crystal) state and an amorphous state. In the poly-crystalline state, each grain of the present phase change material is a perfect crystal and the phase change material is conductive (almost metallic). It is notable, however, that each of the grains is randomly oriented with respect to the other grains resulting in an overall poly-crystalline material. In the amorphous state, there is no order in the material and the phase change material is highly resistive. These two states make the present phase change materials particularly well-suited for storing data.

At block 104, the phase change device is placed in a plasma chamber. Plasma is generated (at block 106) from a halogen gas within a vacuum or plasma chamber. Plasma is generated by applying a radio frequency (RF) or microwave energy to ionize the gas. The upper layers, which may comprise the lithographic stack, are subject to plasma etching (at block 108), including chemical etching and physical etching, to pattern a hardmask layer of the lithographic stack, which may comprise titanium nitride (TiN). The etching of the upper layers may be performed when the phase change device is at a temperature of approximately 40° C. and 80° C. Chemical etching occurs when the reactive species in the plasma chemically reacts with the material to be etched, forming volatile products that can be pumped away. Physical etching occurs when plasma and other non-reactive materials, such as argon (Ar), are accelerated toward the phase change material. For all the etching steps, the halogen and the argon may be introduced into the chamber at the same time to perform chemical etching and physical etching at the same time. Alternatively, the halogen chemical etching may be performed first, followed by the sputtering.

The halogen used for plasma etching may comprise a Fluorine species (e.g., SF₆, CF₄, CHF₃, C₄F₈) or a chlorine species (e.g., Cl₂, BCl₃, HBr). In certain embodiments, the flow rate at which argon is introduced into the plasma chamber may be approximately 200 standard cubic centimeter per minute (sccm) and the flow rate at which chloride is introduced into the plasma chamber may be approximately 35 sccm.

Etching is performed (at block 110) on the etch stop layer above the phase change material in the plasma chamber. The etching of the etch stop layer may be performed at the same temperature at which the etching of the lithographic stack is performed. In described embodiments, no passivation elements are introduced, such as CxHy passivation species, e.g., CH₄, C₂H₂, C₂H₄, C₂H₆, etc., and only the halogen is used to generate the plasma.

After etching the etch stop layer above the phase change material, the temperature of the phase change device within the chamber is reduced (at block 112) to a target temperature such as approximately between −50° C. and −20° C. Upon the phase change device reaching the target temperature, etching is performed (at block 114) on the phase change material through the patterned hardmask.

The etching operations in FIG. 1 may be performed for a standard etching duration depending on the layer thickness and plasma properties (ion flux, energy, etc.), which determine the etch rate.

Chemical etching at the low temperature results in an elemental trace of the halogen, inhibits damage to the phase change material and avoids redeposition of materials on the sidewall of the phase change material.

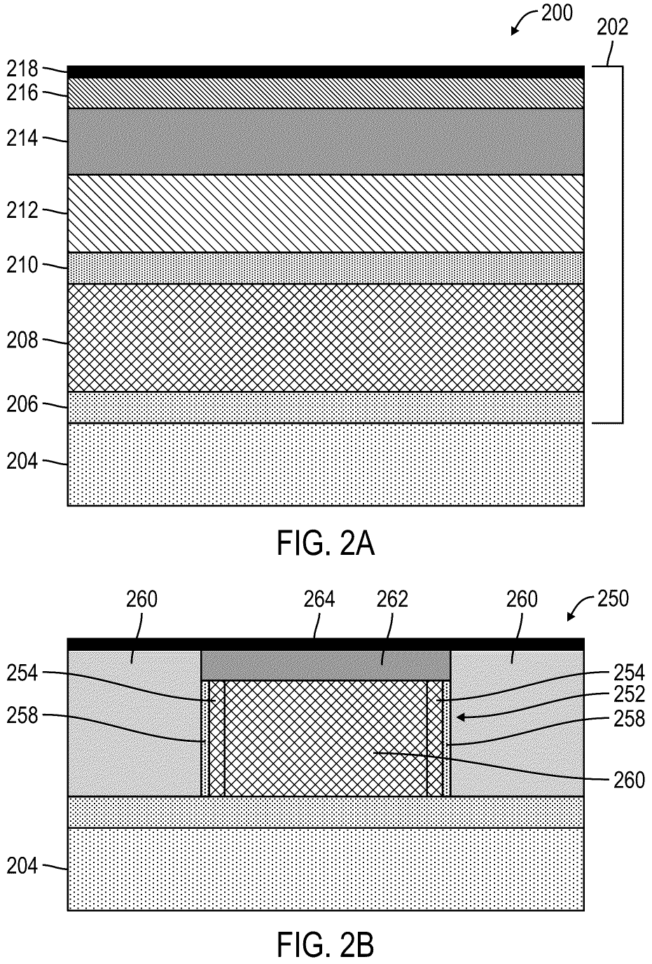

FIG. 2 provides an embodiment of a phase change memory device 200 formed at step 102 in FIG. 1 and subject to the plasma etching process described at blocks 104-116. At step 102, the formed phase change memory device 200 comprises a phase change memory device stack 202 formed on a substrate 204. The substrate 204 may comprise a bulk semiconductor wafer, such as a bulk Si, bulk Ge, bulk SiGe and/or bulk III-V semiconductor wafer, or an SOI wafer with an SOI layer formed form a semiconductor material(s) such as Si, Ge, SiGe and/or a III-V semiconductor. Further, substrate 302 may already have pre-built structures (not shown) such as transistors, diodes, capacitors, resistors, interconnects, wiring, etc.

Above the substrate 204, a layer 206 is formed, which may comprise silicon nitride (SiN). Layer 206 may comprise an etch stop layer or buffer layer to prevent intermixing of the phase change memory stack 202 materials. Above the layer 206, the phase change material 208 is formed. A wide variety of materials can be employed as the phase change material 208. In one embodiment, the phase change material 208 is a chalcogenide alloy that includes the chalcogenide element Te, in combination with other elements such as Sb and/or Ge, e.g., Sb₂Te₃, GeTe, and/or Ge₂Sb₂Te₅. Alternatively, embodiments are also contemplated herein where phase change material 208 is a non-chalcogenide such as a GaSb and/or Ge—Sb based alloy. Yet further, embodiments are also contemplated herein where at least one of the above chalcogenide and/or non-chalcogenide phase change materials is doped with an additional element(s) such as Ag, In, N, Si and/or Bi to optimize its properties.

Above the phase change material 208 layer, a titanium nitride (TiN) layer 210 is formed, which may function as an etch stop. Above the TiN layer 210, a silicon nitride (SiN) hardmask 212 is formed. Other suitable materials for the hardmask 212 may comprise silicon dioxide (SiO₂), titanium nitride (TiN) and/or silicon oxynitride (SiON). Above the SiN hardmask 212, an organic planarization layer (OPL) 214 is formed. The OPL 214 is an organic layer to provide adequate etch resistance. Following the OPL layer 214 is a silicon anti-reflective coating (SiARC) layer 216. Above the SiARC layer 216, a photoresist layer 218 is formed.

The OPL layer 214, SiARC layer 216, and photoresist layer 218 form a lithographic stack that are etched (at block 108 in FIG. 1) to pattern the SiN hardmask 212 with the footprint and location of at least one phase change memory cell in the phase change device stack 202. Alternatively, hardmask 212 can be formed by other techniques, including but not limited to, sidewall image transfer (SIT), self-aligned double patterning (SADP), self-aligned quadruple patterning (SAQP), and other self-aligned multiple patterning (SAMP). Suitable hardmask 212 materials include, but are not limited to, silicon nitride (SiN), silicon dioxide (SiO₂), titanium nitride (TiN) and/or silicon oxynitride (SiON). An etch is then performed to transfer the pattern from hardmask 212 to the underlying phase change memory device stack 208. A directional (i.e., anisotropic) etching process such as reactive ion etching can be employed for the phase change memory device stack 202 etch.

The layer 210 is etched at block 110 in FIG. 1. The etching at the lower temperature is performed at block 114 in FIG. 1 to transfer the pattern from the hardmask 212 to the underlying phase change memory material 208. A directional (i.e., anisotropic) etching process, such as reactive ion etching, can be employed for the phase change memory material 208. The etching process patterns the phase change memory device stack 202 down to the layer 206 to form the phase change memory cells.

FIG. 2B illustrates an embodiment of the etched phase change memory device 250 including an etched phase change memory cell 252 etched from the phase change material 208 to form a sidewall 254, a bulk region 256 surrounded by the sidewall 254, and an interface region 258 between the sidewall 254 and a dielectric layer 260. The elemental composition of the sidewall 254 and bulk region 258 substantially comprise the phase change material. The interface region 256 is comprised of the phase change memory material and includes elemental traces of the halogen, e.g., chloride, used to etch the phase change material 208 in FIG. 2A to produce the phase change cell 252 in FIG. 2B. The interface region 256 interfaces with the surrounding dielectric layer 260. Elemental traces of the halogen may also be found in the sidewalls 254 at a lower concentration than they are found in the interface region 258. The bulk region 254 may be free of the halogen.

In one embodiment, the sidewall 254 may have a depth of 10 nanometers (nm) and the bulk may have a depth of 20 nanometers, and the dielectric material m ay have a depth of 200 nanometers. The dielectric layer 260 may be formed of a 10 nanometer layer of silicon nitride followed by a 200 nanometer layer of silicon oxide.

Further, because passivation gas was not introduced into the plasma chamber while etching the phase change memory device at the reduced temperature, polymers, carbon and other elements are absent from the phase change memory cell 252, including the interface region 258, sidewall 254, and bulk region 256. Other materials that may be deposited through the use of passivation gas, such as hydrocarbons and oxygen, would also be absent from the phase change memory cell 252.

A dielectric material 260 is deposited around the phase change memory cell 252. A top electrode 262 is formed on a top surface of the phase change memory cell 252 to enable read and write access to the phase change memory cell 252. A chemical mechanical planarization process (CMP) may be applied to the upper surface of the phase change device 250 to form a polished surface 264.

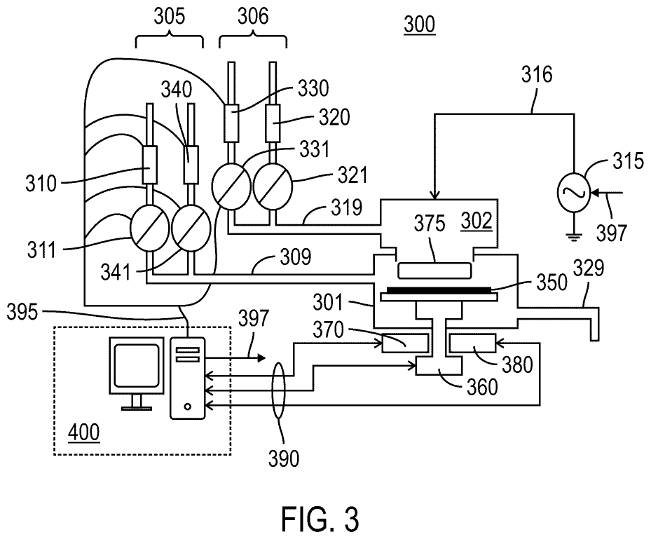

FIG. 3 shows a schematic diagram of an example fabrication apparatus 300 including processing chamber or reactor 301 in which the method of FIG. 1 may be implemented. In an embodiment a single processing chamber is shown, although the processing chamber 301 may be one part of a multi-chambered processing system. Apparatus 300 is generally configured to provide deposition process gases, etch gases, and purge gases 305 to a reactor or processing chamber 301, which can be configured as a reduced pressure process chamber ranging from between 1 Torr and 300 Torr during deposition steps and etch steps. One or more gases 305 are input to processing chamber 301 via an inlet gas manifold 309 provided on one side of the processing chamber 301. The same set or another set of gases 306 can be input to apparatus 300 to produce a plasma 375 within a plasma processing chamber 302 located at or within processing chamber 301. Associated with plasma processing chamber 302 is an RF (radio frequency) or microwave frequency signal generator 315 supplying RF or microwave power 316 to the plasma process chamber for creating the plasma 375.

In an embodiment, the process gases 305 are introduced into plasma processing chamber 302 via an inlet gas manifold 319 provided on one side of the process chamber 302 and provided to the reactor 301. An exhaust manifold 329 is provided on the other side of the processing chamber 301 and may be connected to a vacuum pump (not shown) and a scrubber (not shown). An electrostatic chuck and or susceptor 360 is located in the process chamber 302 that is configured to hold a wafer 350 including at least the physical structures shown in FIG. 2 that are being processed within the plasma processing chamber 302.

In an embodiment, the exemplary apparatus can be configured to provide gases to the process chamber 301, e.g., through gas flow controllers 310, 320, 330, 340 and respective valve 311, 321, 331, 341. The valves 311, 321, 331, 341 can be normally closed and can be opened when the gas flows into the processing chamber 301 or plasma processing chamber 302. Each gas flow controller 310, 320, 330, 340 controls the flow rate of the gas into the processing chamber 301 or plasma processing chamber 302. In one embodiment, the gas flow controllers 310-340 can be configured to provide a flow rate in a range from standard cubic centimeters per minute (sccm) to standard liters per minute (slm).

As shown in FIG. 3, the apparatus 300 can further include temperature controller 370 and pressure controller 380 to ensure target temperatures and pressures within the exemplary process chamber 301 are achieved.

As further shown in FIG. 3, the exemplary process chamber 301 can further include a process control device 400, which can be a computer, a set of interconnected computers, a dedicated standalone computing device, a portable computing device, or any other type of device capable of generating control signals 390 and receiving feedback signals used for controlling the pressure and temperature of the processing chamber 301 and further, generating signals 395 for controlling the respective gas flows into the processing chamber 301 and plasma processing chamber 302, e.g., by activating each of the valves (311, 321, 331, 341) and respective gas flow controllers (310, 320, 330, 340). Further control signals 397 are generated and applied to the RF generator for controlling frequency and power conditions for generating the plasma 375.

In accordance with embodiments herein, the wafer 350 containing formed resistive memory storage device(s) of FIG. 2 is placed within the apparatus 300 and is transferred, under vacuum (air-free) conditions, from a prior etching chamber, to the processing chamber 301 in which the encapsulating dielectric material is deposited while controlling conditions to trim, by plasma etching, the damaged oxidized sidewall surfaces of GST layers.

In an embodiment, process control device 400 further generates control signals for tuning plasma parameters used to generate, inside the process chamber 301, a plasma 375 to accomplish the processes described including simultaneous deposition and etching as described herein.

By tuning plasma parameters, there is generated a plasma 375 of halogen gas at a cryo-etching temperature to etch the phase change material layer without having redeposition of material on the sidewalls so that a passivation gas does not need to be introduced.

For example, plasma tuning conditions for controlling parameters such as RF or microwave powers, frequency, gas flows and chemistry, and plasma pressures are configured to create the plasma 375 for depositing an encapsulating dielectric material and an etching of damaged oxidized sidewall surfaces of GST layers of the resistive memory storage device structure in the same processing chamber, e.g., of a semiconductor fabrication system without exposing the resistive memory storage structure to air between the steps of plasma etching and deposition.

With the described embodiments, etching the phase change material 208 at a very low temperature using a halogen gas inhibits redeposition of material on the sidewall of the layer above the phase change material 208. Further, the low temperature etching causes less oxidation of the sidewall than would occur at a higher temperature. The low temperature, or cryo-etching process, using only halogen chemistry, may cause a chlorine element trace, having a straight profile and no damage to the phase change material 208.

The phase change memory device 200 may be used to form a non-volatile storage device in which an electrical current is used to change the state of a chalcogenide glass material. Phase change memory devices 200 may form the memory cells of a 3D crosspoint memory or other type of non-volatile storage device.

The method and structure described herein are used in the manufacture of integrated circuits. The resulting integrated circuit chips can be distributed by the fabricator in raw wafer form (i.e., a single wafer with multiple unpackaged chips), bare die, or packaged form. In the latter case, the chip is placed in a single-chip package (e.g., a plastic carrier with leads attached to a motherboard or other higher-level carrier) or in a multi-chip package (e.g., a ceramic carrier with surface interconnects and/or or buried connections). In either case, the chip is then integrated with other chips, discrete circuit elements, and/or other signal processing devices as part of either (a) an intermediate product, such as a motherboard, or (b) an end product. The end product can be any product that contains integrated circuit chips, ranging from toys and other simple applications to advanced computer products with a display, keyboard or other input device, and a central processor.

The terminology used herein is for the purpose of describing particular embodiments only and is not intended to be limiting of the invention. As used herein, the singular forms “a”, “an” and “the” include the plural forms as well, unless the context clearly indicates otherwise. It is further understood that the terms “comprises” and/or “comprising” when used in this specification specify the presence of particular features, integers, steps, operations, elements and/or components, but the presence or addition one or more other features, integers, steps, operations, elements, components and/or groups thereof. “Optional” means that the event or circumstance described below may or may not occur and that the description includes instances where the event occurs and instances where it does not occur.

Approximate formulations, as used in the specification and claims herein, may be used to modify any quantitative representation that is permissible may vary without leading to a change in the basic function to which it relates. Accordingly, a value modified by one or more of the terms “approximately,” “approximately,” and “substantially” is not limited to the precise value specified. In at least some cases, the approximate formulation may correspond to the accuracy of an instrument used to measure the value. Here and throughout the specification and claims, range boundaries may be combined and/or interchanged; such areas are identified and include all sub-areas therein, unless the context or language indicates otherwise. The term “approximately” applied to a specific value of a range refers to both values and, unless otherwise dependent on the accuracy of the measurement instrument, can mean +/ −10% of the declared value(s).

In discussing the present technology, it may be helpful to describe various salient terms. In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other directions) and the spatially relative descriptors used herein should be interpreted accordingly.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting.

The description of the present disclosure has been presented for purposes of illustration and description, but is not intended to be exhaustive or limited to the disclosure in the form disclosed. Many modifications and variations will be apparent to those of ordinary skill in the art, and structure or logical changes may be made without departing from the scope and spirit of the disclosure. In particular, elements of the embodiments described hereinafter may be combined with elements of different embodiments. The embodiment was chosen and described in order to best explain the principles of the disclosure and the practical application, and to enable others of ordinary skill in the art to understand the disclosure for various embodiments with various modifications as are suited to the particular use contemplated

What is claimed is:

1. A method for etching a phase change material of a phase change memory device, comprising:
lower a temperature of the phase change memory device to a target temperature;
and applying a plasma etching process to pattern the phase change material in response to cooling the temperature of the phase change memory device to the target temperature.

2. The method of claim 1, wherein the target temperature is between approximately −50° C. and −20° C.

3. The method of claim 1, wherein no passivation gas is introduced during the plasma etching process.

4. The method of claim 1, further comprising:
forming a plasma gas for the plasma etching process using halogens.

5. The method of claim 4, wherein the plasma gas comprises chlorine gas.

6. The method of claim 1, wherein the plasma etching processes uses argon for physical etching and uses chlorine for chemical etching of the pattern on the phase change material.

7. The method of claim 6, wherein the argon is introduced at a flow rate of 200 standard cubic centimeters per minute (sccm) and the chlorine is introduced at a flow rate of 15 sccm.

8. The method of claim 1, wherein the plasma etching at the target temperature occurs without redeposition on sidewalls of the phase change material.

9. A method for etching a phase change material of a phase change memory device, comprising:
providing the phase change memory device in a stack including a substrate, a plurality of lower layers between the substrate and a lower side of the phase change material, and a plurality of upper layers above an upper side of the phase change material;
etching the upper layers including at least one layer of the upper layers;
decreasing a temperature of the phase change memory device to a target temperature after etching the upper layers; and
applying a plasma etching process to pattern the phase change material in response to the decreasing the temperature of the phase change memory device to the target temperature.

10. The method of claim 9, wherein the target temperature is between approximately −50° C. and −20° C.

11. The method of claim 9, wherein the target temperature comprises a first target temperature, wherein a first upper layer of the upper layers is adjacent to the phase change material in the stack, and wherein the first upper layer is etched at approximately a second target temperature higher than the first target temperature.

12. The method of claim 11, wherein the second target temperature is between approximately 40° C. and 80° C.

13. The method of claim 9, wherein the plasma etching process uses halogen chemistry to pattern the phase change material.

14. The method of claim 9, wherein the upper layers include a titanium nitride layer, a silicon nitride layer, an organic planarization layer, a silicon-containing anti-reflective coating layer, a photoresist layer, wherein the upper layers are etched at temperatures higher than the target temperature to reach the phase change material.

15. A semiconductor memory device, comprising:
a phase change memory cell;
sidewall regions of the phase change memory cell on sides of the phase change material;
an interface region extending along an outer surface of the sidewall regions, wherein the interface region includes trace elements of halogen used in etching the phase change memory cell, and wherein the interface region and the sidewall are free of carbon;
a bulk region of the phase change memory cell between the sidewalls.
a top electrode formed on an upper surface of the phase change memory cell for enabling read or write access to the phase change memory cell.

16. The semiconductor device of claim 15, wherein the bulk region is free of carbon.

17. The semiconductor device of claim 15, wherein the sidewall region includes elemental traces of the halogen at lower concentrations than the elemental traces of the halogen on the interface region.

18. The semiconductor device of claim 15, further comprising:
a dielectric material formed to surround the phase change memory cell and in contact with the interface region.

19. The semiconductor device of claim 15, wherein a depth of the sidewall region is less than a depth of the bulk region.

20. The semiconductor device of claim 15, wherein the halogen comprises chlorine.

21. A method for etching a phase change material of a phase change memory device, comprising:
plasma etching layers of a stack including the phase change memory device above the phase change material at a first temperature;
plasma etching with a halogen at a second temperature the phase change material to form a phase change memory cell, wherein the second temperature is less than the first temperature, and wherein the etched phase change memory cell comprises:
sidewall regions of the phase change memory cell on sides of the phase change material;
an interface region extending along an outer surface of the sidewall regions, wherein the interface region includes trace elements of halogen used in etching the phase change memory cell, and wherein the interface region and the sidewall are free of carbon; and
a bulk region of the phase change memory cell between the sidewalls; and
forming a top electrode formed on an upper surface of the phase change memory cell for enabling read or write access to the phase change memory cell.

22. The method of claim 21, wherein the plasma etching with the halogen forms the bulk region free of carbon.

23. The method of claim 21, wherein the plasma etching with the halogen forms the sidewall region with elemental traces of the halogen at lower concentrations than the elemental traces of the halogen on the interface region.

24. The method of claim 21, further comprising:
forming a dielectric material to surround the phase change memory cell and in contact with the interface region.

25. The method of claim 21, wherein a depth of the sidewall region is less than a depth of the bulk region.
